(19) United States
(12) Patent Application Publication
(10) Pub. No.: US 2012/0306074 A1
(43) Pub. Date: Dec. 6, 2012

(54) SEMICONDUCTOR CHIP HAVING BUMP ELECTRODE, SEMICONDUCTOR DEVICE HAVING THE SEMICONDUCTOR CHIP, AND METHOD FOR MANUFACTURING THE SEMICONDUCTOR DEVICE

(75) Inventor: Yasuko Kobayashi, Tokyo (JP)

(73) Assignee: Elpida Memory, Inc.

(21) Appl. No.: 13/479,806

(22) Filed: May 24, 2012

(30) Foreign Application Priority Data
May 30, 2011 (JP) 2011-120161

(51) Int. Cl. H01L 23/488

(52) U.S. Cl. 257/737; 257/E23.068

(57) ABSTRACT

A semiconductor chip includes: a substrate; a first bump electrode formed on one face of the substrate; a second bump electrode formed on other face of the substrate; and a conductive bonding material layer formed on a top face of at least one of the first bump electrode and the second bump electrode. The first bump electrode has a convex top face and the second bump electrode has a concave top face.

This application is based upon and claims the benefit of priority from Japanese patent application No. 2011-120161, filed on May 30, 2011, the disclosure of which is incorporated herein in its entirety by reference.

### BACKGROUND OF THE INVENTION

1. Field of the Invention

The present invention relates to a semiconductor chip having a bump electrode, a semiconductor device having the semiconductor chip, and a method for manufacturing the semiconductor device.

2. Description of the Related Art

JP 2007-214220 A discloses a semiconductor device of a CoC (Chip on Chip) type having a chip laminated body constructed of a plurality of semiconductor chips which are laminated on each other. Each of the semiconductor chips constructing the chip laminated body has a through wiring and a bump electrode formed on a surface of the through wiring. A chip laminated body is formed by bonding a bump electrode of a semiconductor chip to a bump electrode of another semiconductor chip.

In a chip laminated body described in JP 2005-236245 A, a first terminal of a semiconductor chip has a small second terminal formed at a tip thereof. This second terminal and an external terminal are electrically connected to each other by solder of a conductive material in a state where both of them are brought into contact with each other. In this way, a clearance can be secured between an external terminal of the other semiconductor chip or a substrate and the first terminal of the semiconductor chip. The solder is received in and held by this clearance, so that even if the solder is excessively supplied when the semiconductor chip is mounted, the solder can be prevented from being squeezed out from the terminal. As a result, it is thought that a short circuit between the terminals can be prevented.

In the semiconductor chip described in JP 2007-214220 A, the top face of a bump electrode formed on the semiconductor chip is made flat. When the bump electrodes each having a flat top face are bonded to each other via a conductive bonding material like solder, the melted solder can be squeezed out to the side of the bump by a load applied from a bonding tool. In particular, in a case where the pitch between the bump electrodes is narrow, there is a high possibility that when the solder is squeezed out sideways, this will cause a short circuit in the bump electrodes that are adjacent to each other.

In order to form a through wiring, the semiconductor chip is made thin and has a thickness of, for example, 50 μm. When thin semiconductor chips like this are bonded to each other, the amount of solder as a conductive bonding material needs to be increased so as to stabilize the bonding. In this case, there is an increased possibility that a short circuit will be caused in the bump electrodes that are adjacent to each other when bonding material is squeezed out in a lateral direction when the bump electrodes are bonded to each other.

In the technique described in JP 2005-236245 A, the solder can be prevented from being squeezed out but the bump electrodes is likely to be slid sideways by a load applied thereto when the bump electrodes are flip-chip bonded to each other. When the bump electrodes are slid sideways, the bump electrodes in one chip will be shifted from the bump electrodes another chip. As a result, this will cause poor bonding between the bump electrodes or a short circuit.

Thus, it is desired to prevent the bump electrodes from sliding sideways and to prevent the bonding material for bonding the bump electrodes from being squeezed out.

### SUMMARY

In one embodiment, a semiconductor chip includes: a substrate; a first bump electrode formed on one face of the substrate; a second bump electrode formed on other face of the substrate; and a conductive bonding material layer formed on a top face of at least one of the first bump electrode and the second bump electrode. The first bump electrode has a convex top face and the second bump electrode has a concave top face.

In another embodiment, a semiconductor device in another aspect of the present invention includes a chip laminated body in which the semiconductor chips described above are laminated on each other. The first bump electrode of a first semiconductor chip constructing the chip laminated body and the second bump electrode of a second semiconductor chip constructing the chip laminated body are bonded to each other.

In further embodiment, a method for manufacturing a semiconductor device in still another aspect of the present invention includes: preparing a plurality of semiconductor chips described above; and flip-chip bonding the first bump electrode of the first semiconductor chip of the plurality of semiconductor chips and the second bump electrode of the second semiconductor chip of the plurality of semiconductor chips by using the conductive bonding material layer.

According to the construction described above, when the first bump electrode of one semiconductor chip is bonded to the second bump electrode of the other semiconductor chip, the convex top face of the first hump electrode is engaged with the concave top face of the second bump electrode. This can prevent the bump electrodes from sliding sideways. Further, the conductive bonding material is held in the concave top face of the second bump electrode, so that the bonding material layer can be also prevented from being squeezed out.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic section view of a semiconductor device of a first embodiment;

FIG. 2 is a schematic section view, on an enlarged scale, of a portion near a through wiring of a semiconductor chip;

FIG. 3 is a schematic section view, on an enlarged scale, of a bond part between chips of a chip laminated body or a complex chip laminated body;

FIG. 4A to FIG. 4F are process views showing steps of a process for forming a first bump electrode on a semiconductor wafer;

FIG. 5A to FIG. 5F are process views showing steps of a process for forming a second bump electrode on a semiconductor wafer;

FIG. 6A to FIG. 6C are process views showing steps of a process for forming a chip laminated body and a complex chip laminated body;

FIG. 7A to FIG. 7C are process views showing steps of a process for forming a first sealing resin layer on a complex chip laminated body;

FIG. 8A to FIG. 8D are process views showing steps of a process for mounting a complex chip laminated body on a wiring board to thereby manufacture a semiconductor device;

FIG. 9 is a schematic section view, on an enlarged scale, of a portion near a through wiring of a semiconductor chip in a second embodiment; and

FIG. 10 is a schematic section view, on an enlarged scale, of a bond part between chips of a chip laminated body or a complex chip laminated body having semiconductor chips in the second embodiment.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

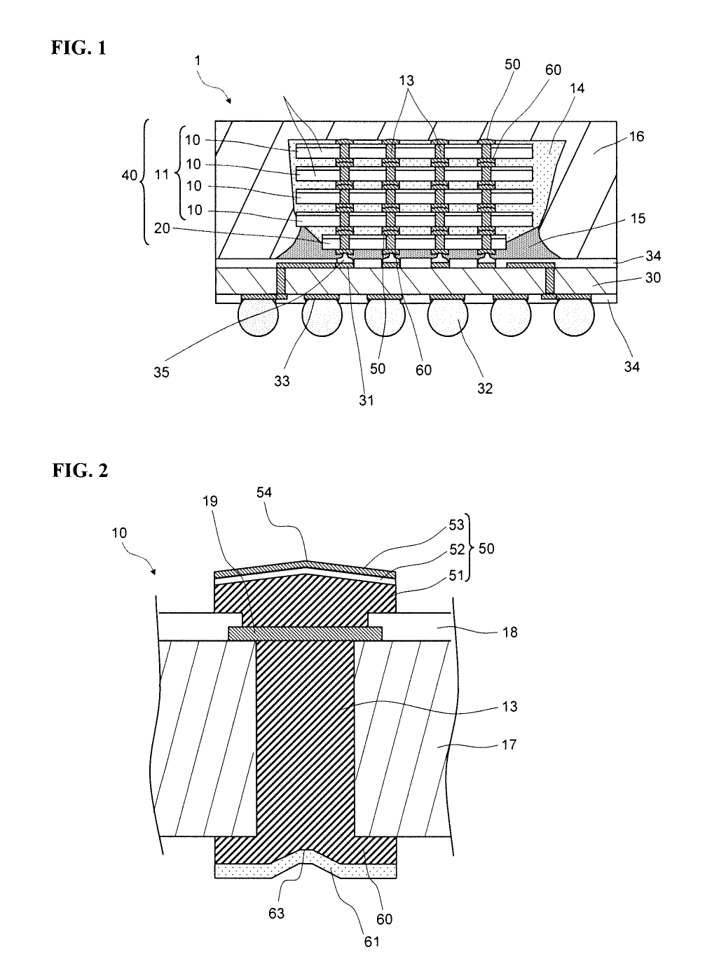

FIG. 1 is a schematic section view of a semiconductor device in a first embodiment. This semiconductor device 1 has a chip laminated body 11 constructed of a plurality of semiconductor chips 10 that are laminated on each other. An interface chip 20 (hereinafter referred to as “IF chip 20”) is arranged under chip laminated body 11. A semiconductor chip 10 on the bottom layer of chip laminated body 11 is connected and fixed to a wiring board 30 via IF chip 20.

Semiconductor chip 10 and IF chip 20 each have one face on which a circuit is formed and the other face on which a circuit is not formed. In the following description of the faces of semiconductor chip 10 and IF chip 20, the face on which the circuit is formed is referred to as an “obverse face”, and the face opposite to the obverse face is referred to as a “reverse face” and is differentiated from the obverse surface. However, this differentiation is made only for convenience of description.

A memory chip having a memory circuit formed on the obverse face thereof can be used as semiconductor chip 10. Instead of this, a chip having a desired circuit formed on the obverse face thereof can be used as semiconductor 10. On the obverse face of IF chip 20 is formed a circuit for controlling semiconductor chip 10. Here, IF chip 20 is also a kind of the semiconductor chip.

Semiconductor chip 10 and IF chip 20 each have bump electrodes 50, 60 formed respectively on the obverse face and the reverse face thereof. Further, in each of chips 10, 20, bump electrode 50 that is formed on the obverse face and bump electrode 60 that is formed on the reverse face are connected to each other via through wiring 13.

In this regard, IF chip 20 also acts as a support member for receiving stress applied to semiconductor chip 10 in the process for manufacturing semiconductor 1. Specifically, IF chip 20 receives stress generated by the thermal expansion or contraction of through wiring 13 in semiconductor chip 10. Bump electrodes 50, 60 of IF chip 20 are arranged in correspondence to the positions of connection pads 31 on wiring board 30.

In the following description, a laminated body including chip laminated body 11 and IF chip 20 is referred to as “a complex chip laminated body 40”, and complex chip laminated body 40 is differentiated from chip laminated body 11. However, this differentiation is made only for convenience of description. Complex chip laminated body 40 is also a chip laminated body constructed of a plurality of semiconductor chips that are laminated on each other.

The clearance between IF chip 20 and semiconductor chip 10 in complex chip laminated body 40 is buried by first sealing resin layer 14. Further, the clearance between respective semiconductor chips 10 is also buried by first sealing resin layer 14. Still further, a portion of a side face of complex chip laminated body 40 is covered with first sealing resin layer 14. As shown in FIG. 1, first sealing resin layer 14 has a nearly trapezoidal section when semiconductor device 1 is viewed from the side. First sealing resin layer 14 is formed of, for example, an underfill material.

IF chip 20, which is arranged on the short side of first sealing resin layer 14 having a nearly trapezoidal section, that is, on the side corresponding to the upper side of the trapezoidal section, has wiring board 30 connected and fixed thereto, wiring board 30 having a given wiring formed thereon. As wiring board 30 is used, for example, a glass epoxy substrate having a given wiring is formed on each of both faces thereof.

Wiring board 30 has a plurality of connection pads 31 formed on one face thereof and has a plurality of lands 33 formed on the other face thereof. Connection pads 31 are each connected to bump electrode 60 on IF chip 20 via wire bump 35. Lands 33 each have metal ball 32 fixed thereto, metal ball 32 becoming an external electrode of semiconductor device 1. Connection pads 31 each are electrically connected to each of given lands 33 via a wiring formed in wiring board 30. Wiring board 30, except for connection pads 31 and lands 33, is covered with insulating film 34 made of a solder resist or the like. Lands 33 may be arranged in a lattice shape. However, the arrangement of lands 33 is not limited to the lattice shape.

Complex chip laminated body 40 and wiring board 30 are bonded and fixed to each other by an adhesive material 15 of a NCP (Non-Conductive Paste) or the like. A bond portion of connection pad 31 on wiring board 30 and bump electrode 60 on IF chip 20 is protected by this adhesive material 15. Complex chip laminated body 40 on wiring board 3 is sealed by second sealing resin layer 16.

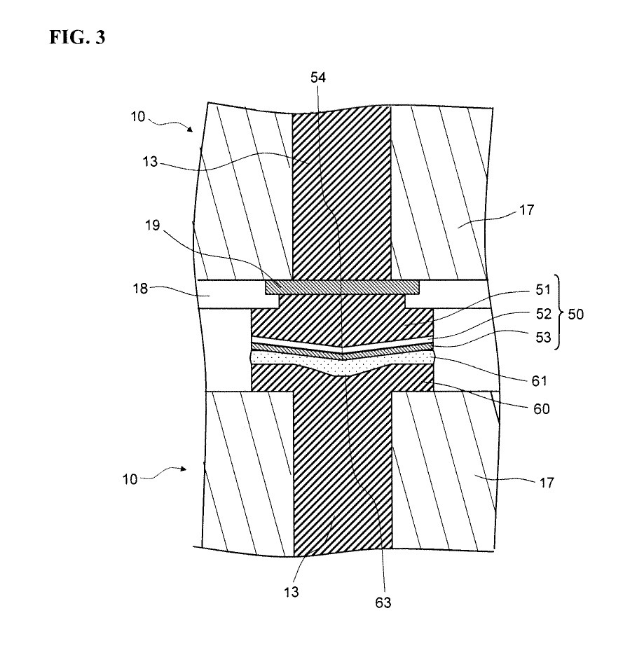

FIG. 2 is a schematic section view, in an enlarged scale, of a portion near a through wiring of a semiconductor chip used for semiconductor device 1. FIG. 3 is a schematic section view, on an enlarged scale, of a bond part between chips 10, 20 of chip laminated body 11 or complex chip laminated body 40.

Semiconductor chip 10 has substrate 17 having electrode pad 19 and a given circuit, for example, a memory circuit formed thereon. A semiconductor substrate made of, for example, silicon can be used as substrate 17. Substrate 17 has insulating layer 18 formed thereon, insulating layer 18 having an opening. Insulating layer 18 is made of a passivation layer, for example, a polyimide layer. An electrode pad 19 is exposed from the opening of insulating layer 18.

Substrate 17 has first bump electrode 50 formed on the obverse face thereof. Substrate 17 has second bump electrode 60 formed on the reverse face thereof. First bump electrode 50 is formed on electrode 19.

It is recommended that first bump 50 has post portion 51 made of metal, for example, Cu, a diffusion prevention layer 52 formed on the top face of post portion 51, and an oxidation prevention layer 53 formed on a surface of diffusion prevention layer 52. Diffusion prevention layer 52 is formed so as to prevent the metal that forms post portion 51 from being diffused. Diffusion prevention layer 52 can be made of, for example, a Ni layer. Oxidation prevention layer 53 is formed so as to prevent the oxidation of post portion 51 and diffusion prevention layer 52. Oxidation prevention layer 53 can be made of, for example, an Au layer. First bump electrode 50 has convex top face 54.

Substrate 17 has second bump electrode 60 formed on the reverse face thereof. Second bump electrode 60 is made of metal, for example, Cu. Second bump electrode 60 has a conductive bonding material layer 61 formed on the top face thereof, the conductive bonding material layer 61 being formed of, for example, solder. Bonding material layer 61 is used for a bump bonding. Bonding material layer 61 is constructed of a SnAg layer precipitated by, for example, a metal plating method. Second bump electrode 60 has concave top face 63.

Substrate 17 has a through hole formed at a position corresponding to first bump electrode 50. This through hole is filled with a conductive material of Cu or the like. The conductive material forms through wiring 13 passing through substrate 17. Through wiring 13 electrically connects first bump electrode 50 of semiconductor chip 10 to second bump electrode 60 corresponding to this.

In FIG. 2, conductive bonding material layer 61 is formed on top face 63 of second bump electrode 60. In place of this, conductive bonding material layer 61 may be formed on top face 54 of first bump electrode 50. In some cases, conductive bonding material layer 61 may be formed on both of top face 54 of first bump electrode 50 and top face 63 of second bump electrode 60. In this regard, preferably, IF chip 20 also has a construction similar to the construction shown in FIG. 2.

As described above, the plurality of semiconductor chips 10, one of which has first bump electrode 50 having convex top face 54 and that has second bump electrode 60 having concave top face 63, are laminated on each other as shown in FIG. 3. Specifically, first bump electrode 50 of first semiconductor chip 10, which constructs chip laminated body 11 or complex laminated body 40, and second bump electrode 60 of second semiconductor chip 10, which constructs chip laminated body 11 or complex laminated body 40, are bonded to each other via conductive bonding material layer 61. In this way, when first bump electrode 50 of first semiconductor chip 10 and second bump electrode 60 of second semiconductor chip 10 are bonded to each other, convex top face 54 of first bump electrode 50 and concave top face 63 of second bump electrode 60 are engaged with each other. Thus, this can prevent bump electrodes 50, 60 from being slid sideways by a load applied thereto when bump electrodes 50, 60 are flip-chip bonded to each other and hence can inhibit the semiconductor chips from being shifted in position from each other. Further, conductive bonding material 61 is held by concave top face 63 of second bump electrode 60, so that the amount of bonding material layer 61 squeezed out to the outside of bump electrodes 50, 60 is decreased.

Since bonding material layer 61 is prevented from being squeezed out, an electric short circuit between bump electrodes 50, 60 arranged at narrow pitches can be prevented. Thus, bump electrodes 50, 60 can be arranged at narrow pitches. As a result, the size of semiconductor chip 10 can be reduced.

Further, since conductive bonding material 61 is held by concave top face 63 of second bump electrode 60, the bonding strength and the current-carrying capacity of bump electrodes 50, 60 can be enhanced. As a result, a semiconductor device having high reliability can be realized. Still further, also void generation in the bond part between bump electrodes 50, 60 can be inhibited.

A height between the one surface of substrate 17 and convex top surface 54 of first bump electrode 50 may be larger than a height between the other surface of substrate 54 and concave top surface 63 of second bump electrode 60. Moreover, concave top surface 63 of second bump electrode 60 may be larger in width than convex top surface 54 of first bump electrode 50.

A method for manufacturing the semiconductor chip will be described. First, semiconductor wafer (substrate) 17 is prepared. Semiconductor wafer 17 is a wafer having a given circuit and electrode pad 19 formed on a surface of a disk-shaped substrate through a process of diffusion or the like, the disk-shaped substrate being made by slicing a silicon ingot formed by a single crystal pulling-up method or the like. Semiconductor wafer 17 has a given circuit, for example, a memory circuit and electrode pad 19 formed thereon for each individual product forming section thereof. Here, each product forming section of semiconductor wafer 17 is a portion that will become substrate 17 of the semiconductor chip shown in FIG. 1.

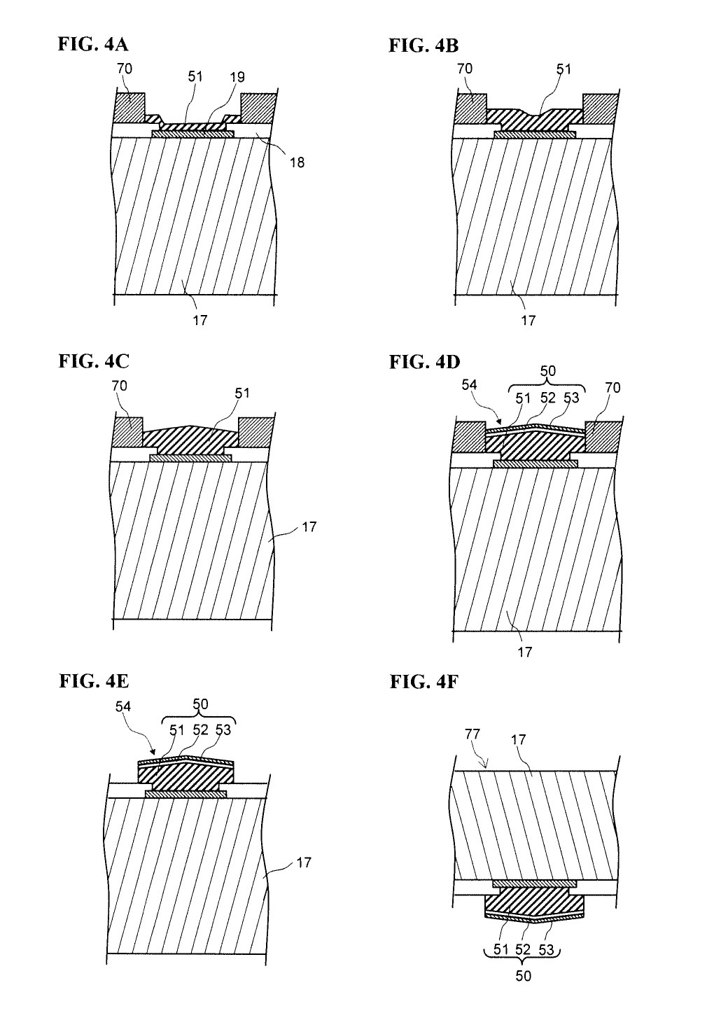

FIG. 4A to FIG. 4F show steps of a process for forming the first bump electrode on semiconductor wafer 17. Electrode pad 19 exposed from insulating film 18 formed on semiconductor wafer 17 has a seed layer (not shown in the drawing), for example, a Cu/Ti layer formed thereon. As shown in FIG. 4A, the seed layer (not shown) has photoresist 70 formed thereon. Photoresist 70 is formed in a given shape for forming the first bump electrode.

Next, electrode pad 19 has post portion 51 formed thereon by a metal plating method, post portion 51 being made of metal. Post portion 51 can be made of metal, for example, Cu. Post portion 51, as shown in FIG. 4A and FIG. 4B, is gradually filled on electrode pad 19. Then, a concave portion at the center is reduced in depth as this metal layer grows, so that the surface shape of post portion 51 can be controlled according to the amount of time that is needed for precipitating the metal. In this way, as shown in FIG. 4C, the top face of post portion 51 is formed in a convex shape.

Next, as shown in FIG. 4D, post portion 51 has a Ni layer as diffusion prevention layer 52 and an Au layer as oxidation prevention layer 53 formed on the surface thereof by the metal plating method. Diffusion prevention layer 52 and oxidation prevention layer 53 are also each formed in a convex shape corresponding to the convex top face of post portion 51. In this way, the top face of the first bump electrode 50 is formed in convex shape 54. Thereafter, the unnecessary seed layer and photoresist 70 are removed, whereby first bump electrode 50 having convex top face 54 is formed, as shown in FIG. 4D.

Semiconductor wafer 17 having first bump electrode 50 formed thereon is held by a support body (not shown), for example, a glass substrate via an adhesive material. At this time, the surface of semiconductor wafer 17 is held by the glass substrate in such a way that first bump electrode 50 is covered with the adhesive material. Preferably, the adhesive material can be foamed or can have its adhesive strength decreased by a given light, for example, a laser light or a UV light and can be removed or peeled off.

As shown in FIG. 4F, semiconductor wafer 17 is ground from reverse face 77 side in a state where semiconductor 17 is held by the glass substrate, thereby being made into a given thickness of, for example, 50 μm. Even in the case of semiconductor wafer 17 having first bump electrode 50 that protrudes, by holding the support substrate in a good condition without damaging bump electrode 50, semiconductor wafer 17 can be easily handled in transportation or the like.

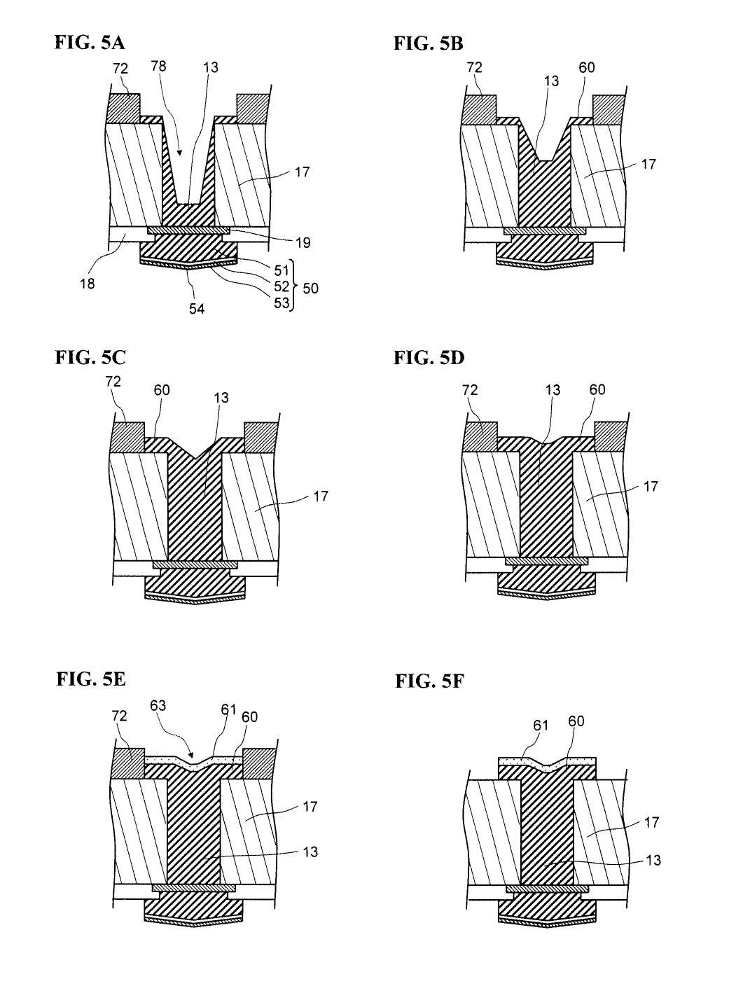

Next, a process for forming the second bump electrode on semiconductor wafer 17 will be described. FIGS. 5A to 5F show the steps of a process for forming the second bump electrode. Thinned semiconductor wafer 17 has through hole 78 formed therein from a reverse face side thereof at a position corresponding to first bump electrode 50. Then, a seed layer (not shown), for example, a Cu/Ti layer is formed on the reverse face of semiconductor wafer 17 and on the side wall of through hole 78. Then, as shown in FIG. 5A, photoresist 72 is formed in a given shape on the seed layer.

As shown in FIG. 5A, the interior of through hole 78 is filled with metal, for example, Cu by the metal plating method. This metal, as shown in FIG. 5A, FIG. 5B, and FIG. 5C, is gradually buried in through hole 78. A concave portion at the center is reduced in depth as the metal layer grows. Further, as shown in these drawings, through wiring 13 in through hole 78 and second bump electrode 60 that protrudes from semiconductor wafer 17 are integrally formed. Precipitation of the plating metal is stopped before the concave portion of the top face of a portion that protrudes from semiconductor wafer 17 is completely buried. In this way, the shape of the top face of the metal can be controlled, whereby the top face of second bump electrode 60 can be formed in concave top face 63 as shown in FIG. 5D.

Next, as shown in FIG. 5E, on the top face of second electrode 60 is formed conductive bonding material layer 61 made of, for example, solder. As for the solder of conductive bonding material layer 61, for example, SnAg can be used and bonding material layer 61 can be formed by the metal plating method. Then, the unnecessary portion of the seed layer and photoresist 72 are removed, whereby second bump electrode 60 having the concave top face is formed as shown in FIG. 5F.

Since through hole 78 is buried to thereby form through wiring 13 and to integrally form through wiring 13 and second bump electrode 60, the time required to form through wiring 13 and second bump electrode 60 can be shortened and hence throughput can be improved. Further, by controlling the precipitation time of the metal by the metal plating method, the top faces of first and second bump electrodes 50, 60 can be easily formed in the concave face or in the convex face.

In this regard, in the embodiment described above, the top face of first bump electrode 50 is formed into convex face 54 and the top face of second bump electrode 60 is formed in concave face 53. However, the top face of first bump electrode 50 may be formed in the concave face and the top face of second bump electrode 60 may be formed in the convex face. From the view point of holding the conductive bonding material layer 61 in the concave top face of the bump electrode, it is preferable that the top face of second bump electrode 60 having the conductive bonding material layer 61 formed thereon be formed into the concave face.

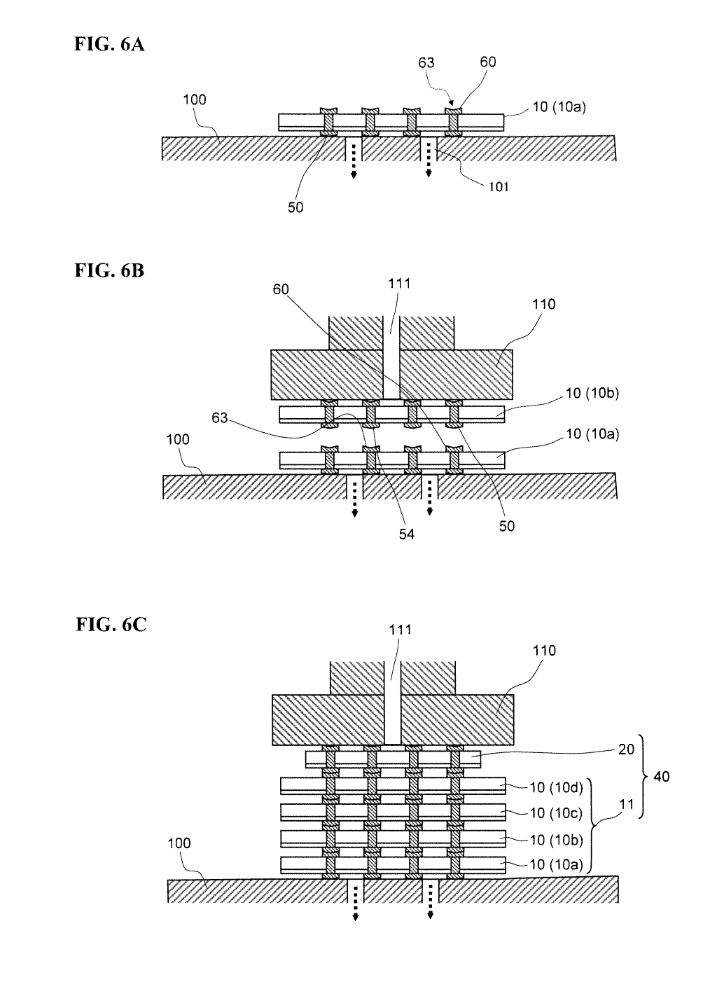

Next, a method for manufacturing semiconductor device 1 shown in FIG. 1 will be described. FIG. 6A to FIG. 6C show steps of a chip lamination process for laminating semiconductor chips 10 on each other. First, a plurality of semiconductor chips 10 are prepared. The structure of each of semiconductor chips 10 is as described above.

As shown in FIG. 6A, semiconductor chip 10a of a first step is placed on stage 100. Semiconductor chip 10a is placed on stage 100 with its reverse face facing up. Semiconductor chip 10a is vacuum-sucked by a vacuum unit (not shown) through suction holes 101 made in stage 100.

As shown in FIG. 6B, semiconductor chip 10b of a second step is placed on semiconductor chip 10a of the first step by the use of bonding tool 110. Semiconductor chip 10b of the second step is placed on semiconductor chip 10a of the first step with its reverse face facing up. In other words, two semiconductor chips 10a, 10b are stacked in such a way that the reverse face of semiconductor chip 10a of the first step is opposite to the obverse face of semiconductor chip 10b of the second step. Here, semiconductor chip 10b of the second step is vacuum-sucked by the vacuum unit (not shown) through suction hole 111 of bonding tool 110 during the period of time that elapses from when semiconductor chip 10b of the second step is held by bonding tool 110 until it is placed on semiconductor chip 10a of the first step. Thus, semiconductor chip 10b of the second step is not dropped from boding tool 110.

Next, second bump electrode 60 on the reverse face of semiconductor chip 10a is press-bonded to first bump electrode 50 on the obverse face of semiconductor chip 10b. Specifically, second bump electrode 60 on semiconductor chip 10a and first bump electrode 50 on semiconductor chip 10b, which are abutted against each other, have heat of a given temperature and a given load applied thereto. For example, bonding tool 110 shown in FIG. 6B is heated to about 200° C. and semiconductor chip 10b of the second step is pressed onto semiconductor chip 10a of the first step by the heated bonding tool 110. At this time, convex face 54 of first bump electrode 50 is engaged with concave face 63 of second bump electrode 60.

Next, by the same procedure described above, semiconductor chip 10c of a third step (see FIG. 6C) is placed on semiconductor chip 10b of the second step, and then the second bump electrode 60 on the reverse face of semiconductor chip 10b is press-bonded to first bump electrode 50 on the obverse face of semiconductor chip 10c. Next, by the same procedure described above, semiconductor chip 10d of a fourth step (see FIG. 6C) is placed on semiconductor chip 10c of the third step, and then second bump electrode 60 on the reverse face of the semiconductor chip 10c is press-bonded to first bump electrode 50 on the obverse face of semiconductor chip 10d.

Thereafter, as shown in FIG. 6C, IF chip 20 is placed on semiconductor chip 10d of the fourth step by bonding tool 110. IF chip 20 is placed on semiconductor chip 10d of the fourth step with its reverse face facing up. Next, second bump electrode 60 on the reverse face of semiconductor chip 10d is press-bonded to first bump electrode 50 on the obverse face of IF chip 20. Specifically, second bump electrode 60 on semiconductor chip 10d of the fourth step and first bump electrode 50 on IF chip 20, which are abutted against each other, have heat of a given temperature and a given load applied thereto. For example, bonding tool 110 shown in FIG. 6C is heated and IF chip 20 is pressed onto semiconductor chip 10d of the fourth step by heated bonding tool 110. In this way, complex chip laminated body 40 that has chip laminated body 11 and IF chip 20 is manufactured.

In semiconductor chip 10 of this embodiment, first bump electrode 50 and second bump electrode 60 are engaged with each other, which can hence prevent first bump electrode 50 and second bump electrode 60 from sliding sideways from each other when first bump electrode 50 and second bump electrode 60 are flip-chip bonded to each other. As a result, the position of semiconductor chips 10 are prevented from being shifted relative to each other. Further, bonding material layer 61 formed on the surface of the bump electrode remains on the concave top face 63 of second bump electrode 60, which can reduce the amount of bonding material layer 61 squeezed out to the outside of bump electrodes 50, 60. As a result, even in the case where bump electrodes 50, 60 are arranged at narrow pitches, it is possible to prevent bump electrodes 50, 60 from causing a short circuit. Still further, it is also possible to inhibit void from being generated in the bond part between bump electrodes 50, 60.

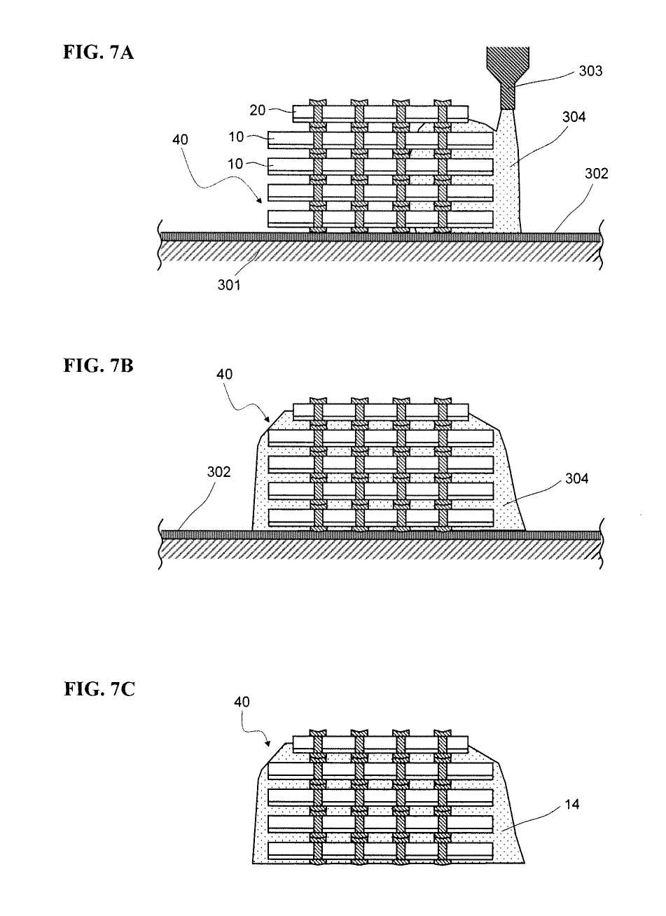

Next, a process for sealing complex chip laminated body 40 will be described. As shown in FIG. 7A, complex chip laminated body 40 is placed on coating sheet 302 placed on a stage 301. Preferably, coating sheet 302, like a fluorine-based sheet or a sheet coated with a silicon-based adhesive material, is made of a material having poor wettability to resin that forms first sealing resin layer 14 (see also FIG. 1). Here, coating sheet 302 does not need to be directly placed onto stage 301. For example, coating sheet 302 may be arranged on a jig or the like placed on stage 301.

Next, as shown in FIG. 7A, complex chip laminated body 40 placed on coating sheet 302 has underfill material 304 supplied thereto by the use of dispenser 303. While the supplied underfill material 304 is forming a fillet around complex chip laminated body 40, underfill material 304 penetrates the clearance between semiconductor chips 10, which are arranged next to each other, by a capillary action. Further, underfill material 304 also penetrates into the clearance between IF chip 20 and semiconductor chip 10.

Coating sheet made of the material that has poor wettability to underfill material 304 is used in this embodiment. Thus, underfill material 304 is prevented from spreading, which can prevent the fillet from increasing in width (see FIG. 7B).

Next, complex chip laminated body 40 covered with underfill material 304 is cured (heat-treated) at a given temperature (for example, about 150° C.), whereby underfill material 304 is thermally cured.

After underfill material 304 is thermally cured, complex chip laminated body 40 is picked up from coating sheet 302 (see FIG. 7C). Coating sheet 302 that has poor wettability to underfill material 304 is used in this embodiment, so that complex chip laminated body 40 can be easily picked up from coating sheet 302.

According to the method described above, complex chip laminated body 40 sealed by first sealing resin layer 14 made of underfill material 304 can be manufactured.

In a case where the position of complex chip laminated body 40 is likely to be shifted when complex chip laminated body 40 has underfill material 304 supplied thereto, complex chip laminated body 40 may be temporarily fixed to coating sheet 302 by the use of a resin adhesive material.

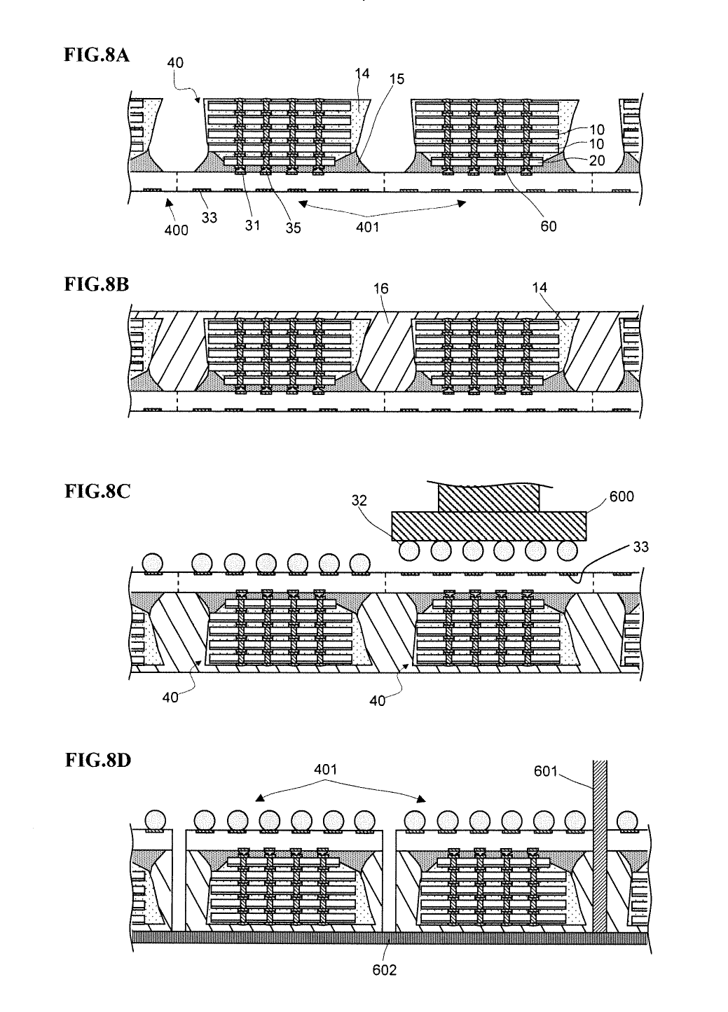

Next, a process for assembling semiconductor device 1 shown in FIG. 1 by the use of complex chip laminated body 40 shown in FIG. 7C will be described by the use of FIG. 8A to FIG. 8D. FIG. 8A to FIG. 8D show one example of the process for assembling semiconductor device 1 shown in FIG. 1. Here, in FIG. 8A to FIG. 8D is shown one example of the process for collectively assembling a plurality of semiconductor devices 1.

First, wiring board 400 is prepared. Wiring board 400 is constructed of a plurality of product forming sections 401 arranged in the shape of lattice. Product forming sections 401 each have a section that finally becomes one wiring board 30 shown in FIG. 1. Each product forming section has a wiring formed thereon, in which the wiring has a given pattern. Further, each product forming section has a plurality of connection pads 31 formed on one face thereof and has a plurality of lads 33 formed on the other face thereof. Still further, each of connection pads 31 has a wire bump 35 formed thereon, wire bump 35 being made of Au or Cu. The functions of connection pad 31, land 33, and wire bump 35 are as described above. Here, by forming wire bumps 35 on wiring board 30, through wirings 13 of chips 10, 20 can be reduced in size and can be narrowed in pitch.

In this embodiment, in order to easily connect complex chip laminated body 40 to connection pads 31, wire bumps 35 are formed on connection pads 31, respectively. However, the bump electrodes on chips 10, 20 may be directly connected to connection pads 31, respectively.

After wiring board 400 is prepared, respective product forming sections 401 have insulating adhesive material 15 applied to the surfaces thereof. Next, complex chip laminated bodies 40 are mounted on the respective product forming sections 401. Next, the respective second bump electrodes 60 on IF chip 20 are bonded to respective wire bumps 35 on the product forming section 401, for example, by a thermocompression bonding method. At this time, the clearance between complex chip laminated body 40 and the product forming section 401 having complex chip laminated body 40 mounted thereon is filled with adhesive material 15, whereby wiring board 400 and complex chip laminated bodies 40 are bonded and fixed to each other (see FIG. 8A). Here, the first sealing resin layer 14 is formed in a tapered shape around complex chip laminated body 40, which can thus prevent adhesive material 15 from creeping up.

Further, in this embodiment, wire pads 35 are formed on connection pads 31 of wiring board 400 and then complex chip laminated bodies 40 are flip-chip mounted in such a way that wire bumps 35 are connected to second bump electrodes 60 of IF chip 20. The top face of second bump electrode 60 of IF chip 20 is formed in the concave face, which can thus prevent second bump 60 and wire bump 35 from shifting sideways from each other. As a result, also the mounting accuracy of complex chip laminated body 40 with respect to wiring board 400 can be improved.

Next, second sealing resin layer 16, which covers the plurality of complex chip laminated bodies 40 in a lump, is formed (see FIG. 8B). Second sealing resin layer 16 can be formed by the use of a molding die having a cavity formed in a given shape. A thermosetting resin, for example, an epoxy resin can be used for second sealing resin layer 16.

In this embodiment, the clearances between respective chips 10, 20 of complex chip laminated body 40 are previously sealed by first sealing resin layer 14, which can thus prevent a void from being generated in the clearances between respective chips 10, 20 when second sealing resin layer 16 is formed.

After second sealing resin layer 16 is formed, a structure shown in FIG. 8B is turned upside down. Then, as shown in FIG. 8C, metal balls, for example, solder balls 32 are mounted on lands 33 formed on wiring board 400. Specifically, the plurality of metal balls 32 are sucked and held by the use of mounting tool 600 having a plurality of suction holes corresponding to respective lands 33 on wiring board 400, and then respective metal balls 32 have flux transferred thereto, and then the plurality of metal balls 32 are mounted in a lump on respective lands 33 of wiring board 400.

After metal balls 32 are mounted on all lands 33, wiring board 400 is reflowed to thereby connect metal balls 32 to lands 33.

After lands 33 are connected to metal balls 32, as shown in FIG. 8D, wiring board 400 is cut by the use of dicing blade 601, whereby wiring board 400 is divided into the product forming sections 401. Wiring board 400 is cut along given dicing lines. When wiring board 400 is cut, product forming sections 401 are held by placing dicing tapes 602 onto second sealing resin layers 16. After wiring board 400 is cut, dicing tapes 602 are removed from the respective product forming sections 401. In this way, semiconductor device 1 shown in FIG. 1 can be manufactured.

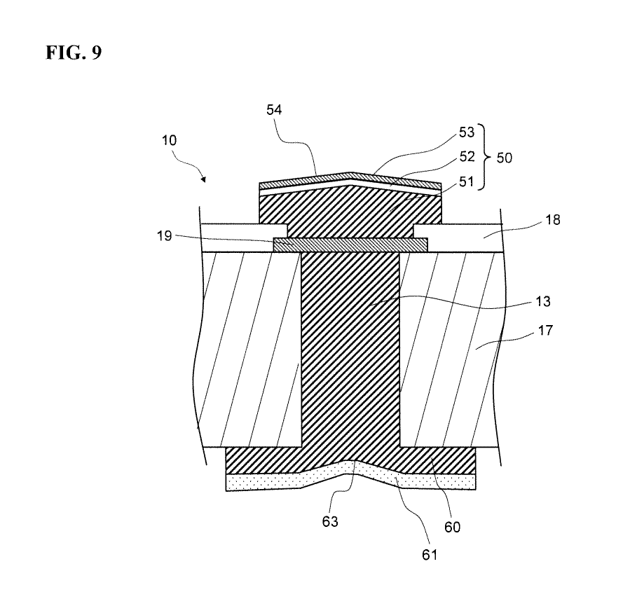

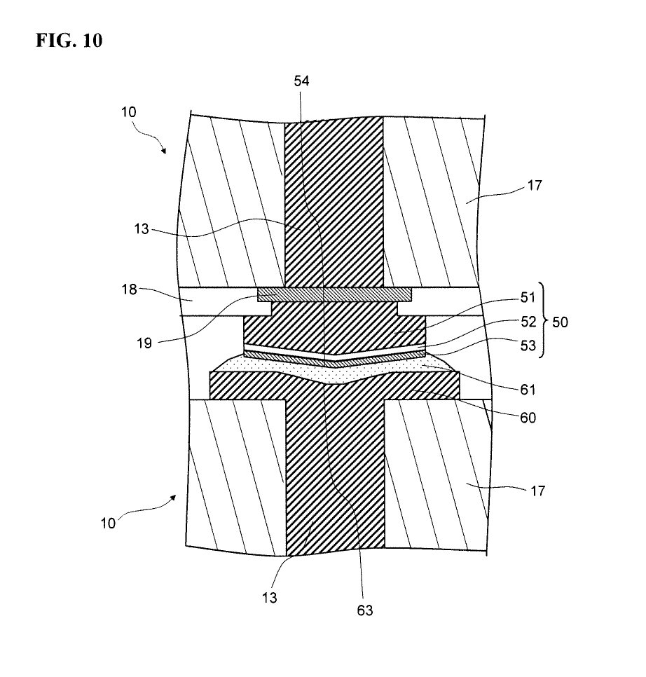

FIG. 9 is a schematic section view, on an enlarged scale, of a portion near a through wiring of a semiconductor chip of a second embodiment.

FIG. 10 is a schematic section view, on an enlarged scale, of a bond part between these semiconductor chips 10 in a chip laminated body or a complex chip laminated body in which semiconductor chips 10 are laminated on each other.

In semiconductor chip 10 of the second embodiment, like the semiconductor chip of the first embodiment, the top face of second bump electrode 60 is concave face 63 and the top face of first bump electrode 50 is convex face 54. However, in semiconductor chip 10 of the second embodiment, as shown in FIG. 9, the area of top face 63 of second electrode 60 is larger than the area of top face 54 of first bump electrode 50.

Specifically, as shown in FIG. 10, top face 63 of second electrode 60 is larger than top face 54 of first bump electrode 50 in such a way that top face 63 of second electrode 60 covers top face 54 of first bump electrode 50 when the semiconductor chips are bonded to each other. In this way, as shown in FIG. 10, when semiconductor chips 10 are flip-chip bonded to each other, bonding material layer 61 wraps around the side of first bump electrode 50 to thereby form a fillet. As a result, the strength by which bump electrodes 50, 60 are bonded to each other can be increased. The other constructions are the same as those in the first embodiment, and hence their descriptions will be omitted.

In the embodiment described above, the complex chip laminated body in which four memory chips and one IF chip are laminated on each other has been described. However, a chip laminated body is not limited to this, and the chip laminated body can use any semiconductor chip if the chip laminated body is constructed in such a way that the bump electrodes of the semiconductor chips are bonded to each other. Further, the number of steps of the lamination of the chip laminated body or the complex chip laminated body can be as many as needed.

Examples of the disclosed invention are as follows.

[Appendix 1]

A semiconductor chip comprising:

a substrate;

a first bump electrode formed on one face of the substrate and having a convex top face;

a second bump electrode formed on other face of the substrate and having a concave top face; and

a conductive bonding material layer formed on the top face of at least one of the first bump electrode and the second bump electrode.

[Appendix 2]

A method for manufacturing a semiconductor device, the method comprising:

preparing a plurality of semiconductor chips according to appendix 1; and

flip-chip bonding the first bump electrode of a first semiconductor chip of the plurality of semiconductor chips to the second bump electrode of a second semiconductor chip of the plurality of semiconductor chips by the conductive bonding material layer.

[Appendix 3]

The method for manufacturing a semiconductor device according to appendix 2, the method comprising:

preparing a wiring board including a connection pad, the connection pad having a wire bump; and

connecting the second bump electrode of the second semiconductor chip to the wiring board via the wire bump.

[Appendix 4]

A method for manufacturing a semiconductor device, the method comprising:

preparing a first semiconductor chip that includes a substrate, a first bump electrode formed on one face of the substrate and having a concave top face, a second bump electrode formed on other face of the substrate and having a concave top face, and a conductive bonding material layer formed on a top face of at least one of the first bump electrode and the second bump electrode; and a second semiconductor chip that includes a substrate; a first bump electrode formed on one face of the substrate and having a convex top face, a second bump electrode formed on other face of the substrate and having a concave top face, and a conductive bonding material layer formed on a top face of at least one of the first bump electrode and the second bump electrode, and

flip-chip bonding the first bump electrode of the first semiconductor chip to the second bump electrode of the second semiconductor chip by the conductive bonding material layer of the first and/or the second semiconductor chip.

[Appendix 5]

The method for manufacturing a semiconductor device according to appendix 4, the method comprising:

preparing a wiring board including a connection pad, the connection pad having a wire bump; and

connecting the second bump electrode of the first semiconductor chip to the wiring board via the wire bump.

Although the inventions has been described above in connection with several preferred embodiments thereof, it will be appreciated by those skilled in the art that those embodiments are provided solely for illustrating the invention, and should not be relied upon to construe the appended claims in a limiting sense.

What is claimed is:

1. A semiconductor chip comprising:
a substrate;
a first bump electrode formed on one face of the substrate and having a convex top face;
a second bump electrode formed on other face of the substrate and having a concave top face; and
a conductive bonding material layer formed on the top face of at least one of the first bump electrode and the second bump electrode.

2. The semiconductor chip according to claim 1,
wherein an area of the top face of the second bump electrode is larger than an area of the top face of the first bump electrode.

3. The semiconductor chip according to claim 1,
wherein the conductive bonding material layer is formed on the top face of the second bump electrode.

4. The semiconductor chip according to claim 1, comprising:
a through wiring that passes through the substrate and electrically connects the first bump electrode to the second bump electrode.

5. The semiconductor chip according to claim 4,
wherein the second bump electrode is formed integrally with the through wiring.

6. The semiconductor chip according to claim 1,
wherein the first bump electrode includes:
a post portion made of metal;
a diffusion prevention layer that is formed on the post portion and that prevents the metal forming the post portion from being diffused; and
an oxidation prevention layer that is formed on the diffusion prevention layer and that prevents the post portion and the diffusion prevention layer from being oxidized.

7. The semiconductor chip according to claim 1, wherein the convex top face of the first bump electrode is higher than the one face of the substrate, and
the concave top face of the second bump electrode is higher than the other face of the substrate.

8. The semiconductor chip according to claim 1, wherein a height between the one surface of the substrate and the convex top surface of the first bump electrode is larger than a height between the other surface of the substrate and the concave top surface of the second bump electrode.

9. A semiconductor device having a chip laminated body in which the semiconductor chips according to claim 1 are laminated on each other,
wherein the first bump electrode of a first semiconductor chip constructing the chip laminated body and the second bump electrode of a second semiconductor chip constructing the chip laminated body are bonded to each other.

10. A semiconductor device, comprising:
a first semiconductor chip including: a substrate; a first bump electrode formed on one face of the substrate and having a convex top face; a second bump electrode formed on the other face of the substrate and having a concave top face; and a conductive bonding material layer formed on a top face of at least one of the first bump electrode and the second bump electrode; and
a second semiconductor chip including: a substrate; a first bump electrode formed on one face of the substrate and having a convex top face; a second bump electrode formed on the other face of the substrate and having a concave top face; and a conductive bonding material layer formed on a top face of at least one of the first bump electrode and the second bump electrode,
wherein the first bump electrode of the first semiconductor chip and the second bump electrode of the second semiconductor chip are bonded to each other by the conductive bonding material layer of the first and/or the second semiconductor chip.

11. The semiconductor device according to claim 10,
wherein an area of the top face of the second bump electrode of the second semiconductor chip is larger than an area of the top face of the first bump electrode of the first semiconductor chip.

12. The semiconductor device according to claim 10,
wherein, in each of the semiconductor chips, the conductive bonding material layer is formed on the top face of the second bump electrode.

13. The semiconductor device according to claim 10,
wherein the first semiconductor chip includes a through wiring that passes through the substrate and electrically connects the first bump electrode of the first semiconductor chip to the second bump electrode of the first semiconductor chip, and
wherein the second semiconductor chip includes a through wiring that passes through the substrate and electrically connects the first bump electrode of the second semiconductor chip to the second bump electrode of the second semiconductor chip.

14. The semiconductor device according to claim 13,
wherein the second bump electrode is formed integrally with the through wiring.

15. The semiconductor device according to claim 10,
wherein the first bump electrode of each of the semiconductor chips includes:
a post portion made of metal;
a diffusion prevention layer that is formed on the post portion and that prevents the metal forming the post portion from being diffused; and
an oxidation prevention layer that is formed on the diffusion prevention layer and prevents the post portion and the diffusion prevention layer from being oxidized.

16. A semiconductor device comprising:
a first semiconductor chip including a first surface and a first bump electrode formed on the first surface, the first bump electrode including a convex top surface;
a second semiconductor chip including a second surface and a second bump electrode formed on the second surface, the second bump electrode including a concave top surface, and the second semiconductor chip stacked over the first semiconductor chip so that the second bump electrode electrically connects to the first bump electrode; and
a conductive bonding material layer provided between the first and second bump electrodes.

17. The semiconductor device according to claim 16, wherein the concave top surface of the second bump electrode is larger in width than the convex top surface of the first bump electrode.

18. The semiconductor device according to claim 16, wherein the conductive material layer is provided between the convex top surface of the first bump electrode and the concave top surface of the second bump electrode.

19. The semiconductor device according to claim 16, wherein the convex top face of the first bump electrode is higher than the first surface of the first semiconductor chip, and the concave top face of the second bump electrode is higher than the second surface of the second semiconductor chip.

20. The semiconductor device according to claim 16, wherein a height between the first surface of the first semiconductor chip and the convex top surface of the first bump electrode is larger than a height between the second surface of the second semiconductor chip and the concave top surface of the second bump electrode.
